(19) United States
(12) Patent Application Publication
(10) Pub. No.: US 2012/0024332 A1
(43) Pub. Date: Feb. 2, 2012

(54) THERMOELECTRIC MATERIAL COATED WITH A PROTECTIVE LAYER

(75) Inventors: Madalina Andreea Stefan, Ludwigshafen (DE); Kerstin Schierle-Arndt, Zwingenberg (DE); Guenther Huber, Ludwigshafen (DE); John Stuart Blackburn, Cheshire (GB); Ivor Wynn Jones, Cheshire (GB); Francis Stackpool, Cheshire (GB); Stephen Heavens, Shropshire (GB)

(73) Assignee: BASF SE, Ludwigshafen (DE)

(21) Appl. No.: 13/262,644

(22) PCT Filed: Mar. 30, 2010
(86) PCT No.: PCT/EP2010/054199

§ 371 Date: Oct. 3, 2011

(30) Foreign Application Priority Data
Apr. 2, 2009 (EP) 09157158.8
Jun. 3, 2009 (EP) 09161747.2

(51) Int. Cl. H01L 35/04; H01L 35/34; H01L 35/28

(52) U.S. Cl. 136/200; 136/233; 136/201

(57) ABSTRACT

A thermoelectric material in a shape for forming part of a thermoelectric module, the thermoelectric material is coated with a protective layer to prevent degradation by humidity, oxygen, chemicals or thermal stress.

The present invention relates to a thermoelectric material which is coated with a protective layer to prevent degradation by humidity, oxygen, chemicals or heat as well as a thermoelectric module comprising the thermoelectric material, as well as a process for preparing the thermoelectric material and module.

Thermoelectric generators and Peltier arrangements as such have been known for some time. p- and n-doped semiconductors which are heated on one side and cooled on the other side transport electrical charges through an external circuit, and electrical work can be performed by a load in the circuit. The efficiency of conversion of heat to electrical energy achieved in this process is limited thermodynamically by the Carnot efficiency. Thus, at a temperature of 1000 K on the hot side and 400 K on the “cold” side, an efficiency of (1000−400):1000=60% would be possible. However, only efficiencies of up to 6% have been achieved to date.

On the other hand, when a direct current is applied to such an arrangement, heat is transported from one side to the other side. Such a Peltier arrangement works as a heat pump and is therefore suitable for cooling apparatus parts, vehicles or buildings. Heating via the Peltier principle is also more favourable than conventional heating, because more heat is always transported than corresponds to the energy equivalent supplied.

A good review of effects and materials is given, for example, by George S. Nolas, Joe Poon, and Mercouri Kanatzidis., Recent Developments in Bulk Thermoelectric Materials, MRS Bulletin, Vol 31, 2006, 199-206.

At present, thermoelectric generators are used, for example, in space probes for generating direct currents, for cathodic corrosion protection of pipelines, for energy supply to light buoys and radio buoys and for operating radios and television sets. The advantages of thermoelectric generators lie in their extreme reliability. For instance, they work irrespective of atmospheric conditions such as atmospheric moisture; there is no fault-prone mass transfer, but rather only charge transfer. It is possible to use any fuels from hydrogen through natural gas, gasoline, kerosene, diesel fuel up to biologically obtained fuels such as rapeseed oil methyl ester.

Thermoelectric energy conversion thus fits extremely flexibly into future requirements such as hydrogen economy or energy generation from renewable energies.

A particularly attractive application is the use for converting (waste) heat to electrical energy in motor vehicles, heating systems or power plants. Thermal energy unutilized to date can even now be recovered at least partly by thermoelectric generators, but existing technologies achieve efficiencies of significantly below 10%, and so a large part of the energy is still lost unutilized. In the utilization of waste heat, there is therefore also a drive toward significantly higher efficiencies.

The conversion of solar energy directly to electrical energy would also be very attractive. Concentrators such as parabolic troughs can concentrate solar energy into thermoelectric generators, which generates electrical energy.

However, higher efficiencies are also needed for use as a heat pump.

Thermoelectrically active materials are rated essentially with reference to their efficiency. A characteristic of thermoelectric materials in this regard is what is known as the Z factor (figure of merit):

$$Z = \frac{{S}^{2} \cdot σ}{κ}$$

with the Seebeck coefficient S, the electrical conductivity σ and the thermal conductivity κ. Preference is given to thermoelectric materials which have a very low thermal conductivity, a very high electrical conductivity and a very large Seebeck coefficient, such that the figure of merit assumes a maximum value.

The product S²·σ is referred to as the power factor and serves for comparison of the thermoelectric materials.

In addition, the dimensionless product Z·T is often also reported for comparative purposes. Thermoelectric materials known hitherto have maximum values of Z·T of about 1 at an optimal temperature. Beyond this optimal temperature, the values of Z·T are often significantly lower than 1.

A more precise analysis shows that the efficiency (is calculated from

$$η = \frac{{T}_{high} - {T}_{low}}{{T}_{high}} \frac{M - 1}{M + \frac{{T}_{low}}{{T}_{high}}}$$

$$where$$

$$M = {[ 1 + \frac{Z}{2} ( {T}_{high} + {T}_{low} ) ]}^{\frac{1}{2}}$$

(see also Mat. Sci. and Eng. B29 (1995) 228).

The aim is thus to provide a thermoelectric material having a maximum value of Z and a high realizable temperature difference. From the point of view of solid state physics, many problems have to be overcome here:

A high σ requires a high electron mobility in the material, i.e. electrons (or holes in p-conducting materials) must not be bound strongly to the atomic cores. Materials having high electrical conductivity σ usually also have a high thermal conductivity (Wiedemann-Franz law), which does not allow Z to be favourably influenced. Materials used at present, such as Bi₂Te₃, already constitute compromises. For instance, the electrical conductivity is lowered to a lesser extent by alloying than the thermal conductivity. Preference is therefore given to using alloys, for example (Bi₂Te₃)₉₀(Sb₂Te₃)₅(Sb₂Se₃)₅ or Bi₁₂Sb₂₃Te₆₅.

For thermoelectric materials having high efficiency, still further boundary conditions preferably have to be fulfilled. For instance, they have to be sufficiently thermally stable to be able to work under operating conditions over the course of years without significant loss of efficiency. This requires a phase which is thermally stable at high temperatures per se, a stable phase composition, and negligible diffusion of alloy constituents into the adjoining contact materials.

In a thermoelectric module the metals/semiconductor materials are joined together by electrodes (for transportation of the generated current) and electrically isolated from other external parts. The electrodes are supported by an electrical insulator material which should allow for a good heat flow from a heat source to the thermoelectric material. Typically, thermoelectric modules incorporate ceramic plates, made for example of SiO₂, Al₂O₃ or AlN as supports having electrical insulating properties in order to prevent short-circuiting of the generated voltages. Crucially for a good heat flow from the heat source to the thermoelectric materials is a good thermally conductive substrate and an excellent joining of the parts for a minimal heat loss. Additionally, several applications, for example applications with mobile or vibrating parts, require also good mechanical stability of the module and its parts.

High temperatures over 400° C. affect the long-time stability of thermoelectric materials. Sublimation is a degradation mechanism that rapidly diminishes the performance of thermoelectric devices and leads to contamination of one n- or p-semiconductor leg by the other, resulting in long-term degradation of the thermoelectric properties and of the module performance. Furthermore, thermoelectric materials oxidise at temperatures above 400° C., which additionally diminishes the efficiency and durability of thermoelectric devices. Thus, a system is needed that minimises oxidation, sublimation and contamination of the thermoelectric material in a thermoelectric module.

U.S. 2006/0090475 and U.S. 2006/0157101 relate to a system and method for suppressing sublimation using opacified aerogel in thermoelectric devices. An aerogel opacified with opacifying or reflecting constituents is used as an interlayer between thermoelectric materials in order to suppress sublimation and to provide thermal insulation in the thermoelectric modules.

We have found that the aerogels as used according to the US-references still do not offer best protection against degradation of the thermoelectric material. Sublimation was suppressed by using aerogels, however oxidation, degradation by thermal stress or humidity or chemical contamination cannot be prevented.

The object of the present invention is to provide a thermoelectric material being better protected against degradation by humidity, oxygen, chemicals or heat.

The object is achieved according to the present invention by a thermoelectric material in a shape for forming part of a thermoelectric module, wherein the thermoelectric material is coated with a protective layer to prevent degradation by humidity, oxygen, chemicals or heat.

The layer thickness can be adjusted as required depending on the coating material. The thickness is chosen so that a substantial prevention of degradation by humidity, oxygen, chemicals or heat is achieved.

The protective layer according to the present invention can be chosen from all suitable protective layers. Preferably, the protective layer contains a ceramic material or a mixture of a ceramic material and glass, to which metal can be admixed. Alternatively, the thermoelectric material can be coated with a layer of a metal, a metal alloy, a semi-metal, a semi-conductor, graphite, graphene, graphane, electrically conductive ceramics and combinations thereof. The layer thickness is chosen so that a minimum electrical and thermal shunt is produced. Surface oxidation of the metal coatings and formation of an oxide layer over the inner metal layer may enhance protection of the thermoelectric legs.

Alternatively, the thermoelectric material is coated with an inner layer of a metal or a metal alloy, a semimetal, a semi-conductor, graphite, graphene, electrically conductive ceramics or combinations thereof and an outer coating containing a ceramic material or a mixture of ceramic material and glass, to which metal can be admixed. The inner layer is directly contacted with the thermoelectric material, whereas the outer layer is coated on the inner layer. The purpose of the inner layer is to achieve a better adhesion of the outer layer with fewer cracks resulting from mismatch of the thermal expansion coefficients.

As an alternative metal and ceramic (or glass) can be combined to adjust the thermal expansion coefficient of the protective coating on the thermoelectric materials. For example, metal powder can be mixed with the ceramic or glass. The amount of metal in the mixture is preferably 50% or less, more preferably 20% or less.

The thermoelectric materials are thereby protected against degradation by the coating layer that has a similar expansion coefficient to that of the thermoelectric material, a low thermal conductivity and low electrical conductivity. The composition of the layer(s) is selected to obtain good adhesion and a good thermal and mechanical stability.

The invention also relates to a thermoelectric module comprising a series of p and n type semiconductors connected in series by conductive contacts, the conductive contacts being supported by a substrate of moderate to high thermal conductivity that is electrically insulated from the conductive contacts by a resistive surface layer, wherein the thermoelectric material of the p and n type semiconductors is coated with a protective layer as defined above.

The object is furthermore achieved by a process for preparing a thermoelectric material as defined above, involving the step of applying the protective coating layer to the thermoelectric material, e.g. by electrophoretic deposition, spraying, sputtering, electrochemical deposition or dip-coating. Further known thin layer deposition techniques can also be applied, as long as the layer thickness assures a sufficient protective function and induces preferably less than 5% heat shunt and less than 1% electrical shunt. It is considered that a satisfactory protection layer will assure during 5000 operation hours less than 5% sublimation loss.

The object is furthermore achieved by the use of the above thermoelectric module for use as a heat pump, for climate control of seating furniture, vehicles and buildings, in refrigerators and (laundry) driers, for simultaneous heating and cooling of streams in processes for substance separation, as a generator for utilizing heat sources or for cooling electronic components.

The object is furthermore achieved by a heat pump, cooler, refrigerator, (laundry) drier, generator for utilizing heat sources, generator for converting thermal energy to electrical energy, comprising at least one thermoelectric module as defined above.

According to the present invention it was found that especially ceramic materials in combination with glass form dense thin electrically insulating barrier layers on thermoelectric material. The thermoelectric module according to the present invention has suitable strength properties and is stable at a continuous operational temperature up to 600° C.

Preferably, the protective layer is formed by a coating of a ceramic material or a glass solder, or a mixture of glass and ceramic material. The ceramic material can be chosen from a wide variety of ceramic materials which have good insulating properties. Preferably, the ceramic material comprises alumina, zirconia, titania, silica, oxides of boron, strontium, barium, phosphorus, lead, tellurium, germanium, selen, antimony, vanadium, hafnium, tantal, zinc, lanthan, yttrium, magnesium, calcium or mixtures thereof. The ceramic material may be employed as a mixture with glass, having a ratio of from 5 to 95% by weight of ceramic material to 95 to 5% by weight of glass, preferably 10 to 90% by weight of ceramic material and 90 to 10% by weight of glass, specifically 20 to 80% by weight of ceramic material and 80 to 20% by weight of glass. Furthermore, it was found that aerogels can be also successfully used as additives in the formulation applied as protective layer.

The protective layer may also be or comprise a metal or a metal alloy, a semimetal, a semiconductor, graphite, electrically conductive ceramics or combinations thereof, preferably a metal or a metal alloy. Preferably, the metal is selected from the group consisting of Ni, Mo, W, Fe, Au, Fe, Ti, Pd, Al, Ag, Si or alloys thereof.

In a further preferred embodiment of the invention, an inner layer of a metal, or a metal alloy, a semi-metal, a semi-conductor, graphite, graphene, graphane, electrically conductive ceramics or combinations thereof is combined with an outer coating of a ceramic material or a mixture of ceramic material and glass. The outer layer can be also produced by partial oxidation of the inner layer (e.g. a coating of the thermoelectric material by aluminium followed by partial oxidation leading to a dense aluminium oxide protective layer).

The thickness of the protective layer is preferably in the range of from 10 nm to 500 μm.

For a ceramic or ceramic glass the coating layer thickness is preferably 1 to 50 μm. For a metal coating, the layer thickness is preferably 100 nm to 10 μm, more preferably 500 nm to 1 μm.

The ceramic glass preferably employed according to the present invention can be prepared from glass with ceramic additives like oxides of Al, Si and/or Pb. The glass gives a uniform coating, and the incorporated ceramic particles enable a thermal expansion without the formation of cracks. Because of the low thermal conductivity of glass (1 W/mK) compared to ceramics (e.g. 30 W/mK for alumina) a high proportion of glass is desirable to minimise the heat shunt. The ceramics are added to improve the expansion coefficient of the glass, especially to minimise the mechanical stress between the glass coating and the thermoelectric material due to different expansion coefficients. Preferably, the ceramic glass coating has very low or no content of oxides of alkali metals. This is advantageous since for example PbTe-thermoelectric materials can be doped with Na to obtain a p-type semi-conductor. Consequently, coatings of PbTe legs with ceramics containing alkali metal ceramics like Na₂O result in a PbTe contamination with Na which degrades thermoelectric properties. Thus, according to the present invention, the protective layer is preferably free of alkali metals.

The metal or metal alloy coating of the thermoelectric material according to one aspect of the invention can be prepared by usual thin layer deposition methods. Examples of such methods are electrochemical deposition, sputtering, MBE, PVD, CVD, chemical deposition, dip-coating and sintering, pressing and/or etching/cutting, dip-coating, spin-coating, rolling of thin-plate metal on the material etc. It is possible to form one metal layer only, however, it is furthermore possible to form several successive layers of the same or different metals. For example, a thin layer of Pt was deposited to protect the thermoelectric material legs, followed by a Ni-layer which adheres better to Pt than to PbTe materials.

The metal layer can cover the complete surface of a thermoelectric leg, or only the part of the leg which is not electrically contacted by the electrodes. For a better oxidation protection the complete coating is preferred.

Instead of a metal layer, the thermoelectric material can also be coated by ceramic oxides, like TCO, ITO, AZO, ATO, FTO or doped TiO₂. Metals are, however, more preferred than electrically conductive ceramics.

This invention allows for a protection of the thermoelectric material by a simple application of the protective layer. Thermoelectric legs can be directly coated, or prepared rods can be first coated and then cut into thermoelectric material legs. Application of protective layers is possible on any geometrical form of the thermoelectric material legs, e.g. in cubic, plate, cylinder, ring form etc. The size of the legs can be adjusted according to the needs of the specific use of the thermoelectric module.

According to the present invention, it is possible to embed, clamp or insert the coated thermoelectric materials in a solid matrix, wherein the matrix material has a low thermal and electrical conductivity and preferably is a ceramic, glass, mica, aerogel or a combination of these materials. The matrix offers module stability, an easier module manufacture and additionally protects the thermoelectric system (materials and contacts) from degradation and contamination due to external factors like humidity, oxygen or chemicals.

This matrix can be clamped or inserted between two electrically isolated (metal) substrates (according to the invention disclosed in the European patent application 09 157 158.8) to form the complete thermoelectric module. The electrodes can be applied either on the isolated substrate or on the thermoelectric materials. The matrix consists of a material or material mixture with low thermal conductivity, so that the heat flows through the thermoelectric material and not through the matrix. While the above materials are preferred, any non-conductive material with low thermal conductivity may be employed.

As the thermoelectric material, all thermoelectric materials may be employed according to the present invention. Typical thermoelectric materials are e.g. disclosed in U.S. Pat. No. 5,448,109, WO 2007/104601, WO 2007/104603.

The thermoelectric material is preferably a semiconductor, a metal, a metal alloy, a semimetal, or combinations thereof. Semiconductors are preferred: skutterudites, clathrates, Half-Heusler intermetallic alloys, Zintl phases, zinc antimonides, chalcogenides, silicon germanium and lead telluride based materials.

The semiconductor materials can be combined to form thermoelectric generators or Peltier arrangements by methods which are known per se to the person skilled in the art and are described, for example, in WO 98/44562, U.S. Pat. No. 5,448,109, EP-A-1 102 334 or U.S. Pat. No. 5,439,528.

By varying the chemical composition of the thermoelectric generators or Peltier arrangements, it is possible to provide different systems which satisfy different requirements in a multitude of possible applications. The inventive thermoelectric generators or Peltier arrangements thus widen the range of application of these systems.

The present invention also relates to the use of an inventive thermoelectric module
as a heat pump
for climate control of seating furniture, vehicles and buildings
in refrigerators and (laundry) driers
for simultaneous heating and cooling of streams in processes for substance separation such as
absorption
drying
crystallization
evaporation
distillation
as a generator for utilization of heat sources such as
solar energy
geothermal heat
heat of combustion of fossil fuels
waste heat sources in vehicles and stationary units
heat sinks in the evaporation of liquid substances
biological heat sources
for cooling electronic components.
as a generator for converting thermal energy to electrical energy, for example in motor vehicles, heating systems or power plants

The present invention further relates to a heat pump, to a cooler, to a refrigerator, to a (laundry) drier, to a generator for converting thermal energy to electrical energy or to a generator for utilizing heat sources, comprising at least one inventive thermoelectric module.

The present invention is illustrated in detail with reference to the examples described below.

### EXAMPLES

(a) Ceramic Coatings

The powder materials were an yttria partially-stabilized zirconium oxide from MEL Chemicals, and aluminium oxide from Sumitomo Chemical Company. Suspensions of the materials in amyl alcohol were vibro-energy milled. EPD was carried out on PbTe thermoelectric material. The deposition potential was 30 V.

Deposition was carried out for approximately 1 minute and the coated material was then removed from the bath and allowed to dry.

The coating thickness was determined from measurements of the deposit weight and area was approximately 5 μm.

(b) Glass-Ceramic Composite Coatings

A composite glass-ceramic powder suspension suitable for EPD was produced by grinding the glass to a powder, mixing with the Sumitomo alumina powder and dispersing in alcohol. The glass used in this composite was an aluminoborate glass with the composition 46% SiO₂, 25% B₂O₃, 10% Al₂O₃, 4% Na₂O, 3% CaO, 6% SrO and 6% BaO. The coating was uniform, adherent, free of texture and free of porosity or microcracks. The thickness of the glass/alumina coating was 7 μm.

(c) Fired Glass Coating

A suspension of glass powder was produced by grinding 10 g glass to a powder and dispersing it in 20 ml water. The glass used was a lead oxide frit of approximate composition by weight 80% PbO 20% SiO₂. A cylindrical pellet of PbTe 10 mm diameter×10 mm length was dip coated in the glass suspension, heated to 700° C. for 2 minutes and allowed to cool rapidly. The fired coating was adherent, visually uniform with complete coverage and free of pores and defects.

1-10. (canceled)

11. A thermoelectric material, comprising a coating comprising a protective layer which prevents degradation by humidity, oxygen, a chemical, or heat,
wherein the protective layer comprises
an inner layer comprising at least one selected from the group consisting of a metal, a metal alloy, a semimetal, a semi-conductor, graphite, graphene, graphane, and an electrically conductive ceramic; and
an outer coating layer comprising a ceramic material or a mixture of ceramic material and glass, to which metal can be admixed.

12. The thermoelectric material of claim 11, wherein the ceramic material comprises at least one selected from the group consisting of alumina, zirconia, titania, silica, an oxide of boron, strontium, barium, phosphorus, lead, tellurium, germanium, selen, antimony, vanadium, hafnium, tantal, zinc, lanthan, yttrium, magnesium, and calcium.

13. The thermoelectric material of claim 11, wherein a metal is present and comprises at least one selected from the group consisting of Ni, Mo, W, Fe, Au, Fe, Ti, Pd, Al, Ag, and Si.

14. The thermoelectric material of claim 11, wherein a thickness of the protective layer is from 10 nm to 500 μm.

15. A thermoelectric module, comprising a series of p and n type semiconductors connected in series by at least one conductive contact,
wherein the conductive contact is in contact with a substrate of moderate to high thermal conductivity that is electrically insulated from the conductive contacts by a resistive surface layer, and
wherein the thermoelectric material of the p and n type semiconductors is the thermoelectric material of claim 11.

16. The module of claim 15, wherein the substrate comprises at least one selected from the group consisting of a metal, a metal alloy, a semimetal, a semiconductor, graphite, and ceramic.

17. The module of claim 15, wherein the thermoelectric material is embedded, clamped or inserted in a solid matrix, wherein the matrix material has a low thermal and electrical conductivity.

18. A process for preparing the thermoelectric material of claim 11, the process comprising:
applying the protective coating layer to the thermoelectric material.

19. A heat pump, cooler, refrigerator, dryer, generator suitable for utilizing a heat source, or generator suitable for converting thermal energy to electrical energy, comprising at least one thermoelectric module of claim 15.

20. The module of claim 17, wherein the matrix material comprises at least one selected from the group consisting of a ceramic, a glass, mica, and an aerogel.

21. The module of claim 15, wherein the thermal conductivity of the substrate is at least 1 W/mK.

22. The thermoelectric material of claim 11, wherein the inner layer comprises a metal.

23. The thermoelectric material of claim 11, wherein the inner layer comprises a metal alloy.

24. The thermoelectric material of claim 11, wherein the inner layer comprises a semimetal.

25. The thermoelectric material of claim 11, wherein the inner layer comprises a semi-conductor.

26. The thermoelectric material of claim 11, wherein the inner layer comprises graphite.

27. The thermoelectric material of claim 11, wherein the inner layer comprises grapheme.

28. The thermoelectric material of claim 11, wherein the inner layer comprises graphane.

29. The thermoelectric material of claim 11, wherein the inner layer comprises an electrically conductive ceramic.

30. The thermoelectric material of claim 1, wherein a metal is present and comprises at least one selected from the group consisting of Ni, Mo, W, Fe, Au, Fe, Ti, Pd, Al, Ag, and Si.
